(19) United States
(12) Patent Application Publication
(10) Pub. No.: US 2010/0108143 A1
(43) Pub. Date: May 6, 2010

(54) ARTICLES WITH HIGHLY ABRASION-RESISTANT POLYOLEFIN LAYERS

(75) Inventor: Richard Allen Hayes, Beaumont, TX (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I. DU PONT DE NEMOURS AND COMPANY, Wilmington, DE (US)

(21) Appl. No.: 12/610,965

(22) Filed: Nov. 2, 2009

Related U.S. Application Data
(60) Provisional application No. 61/110,438, filed on Oct. 31, 2008.

(51) Int. Cl. H01L 31/00; B32B 7/00

(52) U.S. Cl. 136/259; 428/337

(57) ABSTRACT

An article is disclosed which comprises a substrate and an outermost layer where the outermost layer or a portion thereof adheres to or in contact with the substrate and comprises a polyolefin composition and the article provides long lifetime, highly abrasion-resistant articles for use in a wide range of aggressive environmental conditions and can be used as safety glass or solar cell laminate.

This application claims priority to U.S. provisional application 61/110438, filed Oct. 31, 2008; the entire disclosure of which is incorporated herein by reference.

The invention relates to articles comprising highly abrasion-resistant outermost polyolefin layers that provide protection for the articles to which they are applied.

### BACKGROUND OF THE INVENTION

In arid desert environments, the abrasion of articles by wind-blown sand is a significant issue. This is especially true for transparent articles, such as building glazing, automotive windows and headlamps and the like, and transparent coatings such as on signage and solar cell modules. Sand rapidly abrades, pits and degrades transparent articles and coatings, making them unusable in the manner for which they were intended. For example, windows have reduced clarity as they become frosted. Solar cell modules have reduced power output as the light transmission through the incident layer decreases.

Metal articles coated with ionomer compositions made from acid copolymer compositions comprising an alpha-olefin monomer and an α,β-ethylenically unsaturated carboxylic acid monomer are known (U.S. Pat. Nos. 3,826,628; 4,371,583; 4,438,162; 5,496,652; US2006/0233955; and WO2000/10737). Acid copolymer powder coating compositions are known (U.S. Pat. No. 4,237,037 and U.S. Pat. No. 5,981,086). Metal powder coatings comprising anhydride-grafted polyolefins are disclosed in U.S. Pat. No. 4,048,355. Metal powder coatings comprising acid copolymers are disclosed in U.S. Pat. No. 4,237,037. Corrosion-resistant zinc metal-filled acid-grafted polyolefin metal coatings are disclosed in U.S. Pat. No. 5,091,260.

Polyolefins have been used to produce injection molded articles. Golf balls, especially golf ball covers with thicknesses generally between about 1 to 3 mm and opacified with white and other pigments, have been produced by injection molding processes and overmolding processes to form a polyolefin cover composition over a preformed core. Elastomeric polyolefins have been used in golf ball covers (U.S. Pat. Nos. 5,824,746; 6,034,182; 6,099,416; 6,117,025; 6,213,894; 6,220,972; 6,294,617; 6,299,550; 6,384,136; 6,517,451; 6,646,061; 6,653,403; 6,682,440; 6,699,027; 6,800,690; 6,824,477; 7,128,864; 7,160,207; US2002/0065365; US2005/0269737; and US2006/0043632).

Polyolefins grafted with maleic anhydride have also been used in golf ball covers (U.S. Pat. Nos. 5,543,467; 6,034,182; 6,294,617; 6,384,136; 6,517,451; 6,646,061; 6,653,403; 6,800,690; 6,824,477; US2002/0065365; US2005/0269737; and WO2000/40305).

Safety laminates have contributed to society for almost a century. They are characterized by high impact and penetration resistance and do not scatter glass shards and debris when shattered. For example, safety glass laminates have been widely used in the automobile industry as windshields or side windows. More recently, safety laminates are also being incorporated into building structures as windows, walls, stairs, etc.

Safety laminates may consist of a sandwich of two glass sheets or panels bonded together with a polymeric sheet interlayer. One or both of the glass sheets may be replaced with optically clear rigid polymeric (such as polycarbonate) sheets. Safety laminates may also include multiple layers of glass and/or polymeric sheets bonded together with interlayers of polymeric sheets. The interlayers used in safety laminates may be made from relatively thick polymer sheets, which provide toughness and bondability to the glass in the event of a crack or crash. Widely used interlayer materials include complex, multicomponent compositions based on poly(vinyl butyral) (PVB), poly(urethane) (PU), poly(ethylene vinyl acetate) (EVA), ionomers, and the like.

Safety laminates that incorporate elastomeric polyolefin interlayers are known (U.S. Pat. Nos. 3,762,988; 4,303,739; 4,952,460; 5,792,560; 6,159,608; 6,423,170; 6,432,522; 6,559,230; and WO2008036222). Safety laminates that incorporate maleic anhydride-grafted polyolefin interlayers are known (U.S. Pat. No. 5,759,698).

As a sustainable energy resource, the use of solar cell modules is rapidly expanding. Solar cells may be categorized into two types based on the light absorbing material used, i.e., bulk or wafer-based solar cells and thin film solar cells. Both types of solar cells incorporate various layers to encapsulate and protect the fragile solar cells. Suitable polymer materials for solar cell encapsulant layers may have a combination of characteristics such as high impact resistance, high penetration resistance, good ultraviolet (UV) light resistance, good long term thermal stability, adequate adhesion strength to glass and other rigid polymeric sheets, and good long term weatherability. Because moisture can cause delamination and corrosion, it is very desirable that solar cell encapsulant layers have high moisture resistance. Furthermore, because the power output is affected by the amount of sunlight reaching the solar cells, it is also desirable that at least the front solar cell encapsulant layer has a low degree of haze.

Recently, ionomers have been used as solar cell encapsulants (U.S. Pat. Nos. 5,476,553; 5,478,402; 5,733,382; 5,741,370; 5,762,720; 5,986,203; 6,114,046; 6,187,448; 6,353,042; 6,320,116; 6,660,930; US20030000568; US20050279401; US20080017241; US20080023063; US20080023064; and US20080099064). Terionomer encapsulant layers are known (U.S. Pat. No. 3,957,537 and U.S. Pat. No. 6,414,236). Ionomer backsheets are known (U.S. Pat. Nos. 5,741,370; 5,762,720; 5,986,203; 6,114,046; 6,187,448; 6,320,116; 6,353,042; 6,586,271; and 6,660,930).

A shortcoming of the art is articles such as safety laminates and solar cell modules with low abrasion resistance, resulting in short service lifetimes. It is desirable to improve the abrasion resistance of these articles to protect them from harsh environmental hazards.

### SUMMARY OF THE INVENTION

The invention provides an article comprising a substrate and an outermost layer on the substrate having a thickness of about 0.1 to about 20 mils (0.0026 to 0.51 mm) comprising a polyolefin composition; the polyolefin comprising ethylene and an α-olefin having 3 to 20 carbons having a density of about 0.92 g/cc (ASTM D-792) or less.

### DETAILED DESCRIPTION OF THE INVENTION

All publications, patent applications, patents, and other references mentioned herein are incorporated by reference in their entirety. Unless otherwise defined, all technical and scientific terms used herein have the same meaning as commonly understood by one of ordinary skill in the art to which this invention belongs. In case of conflict, the present specification, including definitions, will control.

Except where expressly noted, trademarks are shown in upper case.

Although methods and materials similar or equivalent to those described herein can be used in the practice or testing of the present invention, suitable methods and materials are described herein.

Unless stated otherwise, all percentages, parts, ratios, etc., are by weight. When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

When the term “about” is used in describing a value or an end-point of a range, the disclosure should be understood to include the specific value or end-point referred to.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The transitional phrase “consisting of excludes any element, step, or ingredient not specified in the claim, closing the claim to the inclusion of materials other than those recited except for impurities ordinarily associated therewith. When the phrase “consists of appears in a clause of the body of a claim, rather than immediately following the preamble, it limits only the element set forth in that clause; other elements are not excluded from the claim as a whole.

The transitional phrase “consisting essentially of limits the scope of a claim to the specified materials or steps and those that do not materially affect the basic and novel characteristic(s) of the claimed invention. “A ‘consisting essentially of’ claim occupies a middle ground between closed claims that are written in a ‘consisting of’ format and fully open claims that are drafted in a ‘comprising’ format.”

Where applicants have defined an invention or a portion thereof with an open-ended term such as “comprising,” it should be readily understood that (unless otherwise stated) the description should be interpreted to also describe such an invention using the terms “consisting essentially of or “consisting of.”

Use of “a” or “an” are employed to describe elements and components of the invention. This is done merely for convenience and to give a general sense of the invention. This description should be read to include one or at least one and the singular also includes the plural unless it is obvious that it is meant otherwise.

In describing certain polymers it should be understood that sometimes applicants are referring to the polymers by the monomers used to make them or the amounts of the monomers used to make them. While such a description may not include the specific nomenclature used to describe the final polymer or may not contain product-by-process terminology, any such reference to monomers and amounts should be interpreted to mean that the polymer is made from those monomers or that amount of the monomers, and the corresponding polymers and compositions thereof.

The materials, methods, and examples herein are illustrative only and, except as specifically stated, are not intended to be limiting.

The invention is an article comprising a substrate and an outermost layer on the substrate comprising a polyolefin composition. As used herein, “outermost” refers to a layer of a multilayer structure with only one surface in contact with another layer of the multilayer structure and the other surface exposed to the environment. The outermost polyolefin layer provides for long lifetime, highly abrasion-resistant articles for use in a wide range of aggressive environmental conditions. The articles are preferably transparent and include articles such as building glazing, safety laminates, vehicle windows, windshields, headlamps, lighting fixtures and the like, signage and solar cell modules.

Polyolefin Layer Composition

By thermoplastic polyolefin polymer, polyolefin and similar terms used herein, reference is made to a thermoplastic polyolefin comprising copolymerized units of ethylene and an α-olefin having 3 to 20 carbons having a density of about 0.92 g/cc (ASTM D792) or less.

The polyolefin copolymer comprises ethylene and α-olefin comonomers. It comprises at least two monomers, but may incorporate more than two comonomers, such as terpolymers, tetrapolymers and the like. Preferably, the polyolefin copolymer comprises from about 5 wt % to about 50 wt % of the α-olefin comonomer (based on the total weight of the polyolefin copolymer), more preferably about 15 wt % to about 45 wt %, yet more preferably about 20 wt % to about 40 wt %, and most preferably, about 25 wt % to about 35 wt %.

The α-olefin comonomer contains from 3 to 20 carbons and may be a linear, branched or cyclic α-olefin. Preferable α-olefins are selected from the group consisting of propene, 1-butene, 3-methyl-1-butene, 4-methyl-1-pentene, 1-hexene, 1-heptene, 1-octene, 1-decene, 1-dodecene, 1-tetradecene, 1-hexadecene, 1-octadecene, 3-cyclohexyl-1-propene, vinyl cyclohexane and the like and mixtures thereof. The α-olefin comonomer preferably contains 3 to 10 carbons. The density of the α-olefin copolymer will generally depend on the type and level of α-olefin incorporated.

The polyolefin copolymer may optionally incorporate a minor amount of other olefinic comonomers; for example cyclic olefins such as norbornene; styrene; dienes such as dicyclopentadiene, ethylidene norbornene and vinyl norbornene; and the like and mixtures thereof. When included, the optional comonomer may be incorporated at a level of about 15 wt % or less, based on the total weight of the polyolefin copolymer.

The polyolefin does not include α,β-ethylenically unsaturated carboxylic acid or anhydride grafted to the parent polyolefin.

The polyolefin may be produced by any known method and may be catalyzed with any known polymerization catalyst such as, for example, radical-, Ziegler-Natta- or metallocene-catalyzed polymerizations (e.g. U.S. Pat. Nos. 3,645,992; 5,026,798; 5,055,438; 5,057,475; 5,064,802; 5,096,867; 5,132,380; 5,231,106; 5,272,236; 5,278,272; 5,374,696; 5,420,220; 5,453, 410; 5,470,993; 5,703,187; 5,986,028; 6,013,819; 6,159,608; and EP514828).

Preferably, the polyolefin has a density of about 0.90 g/cc or less, more preferably a density of about 0.88 g/cc or less, and most preferably a density of about 0.88 to about 0.84 g/cc. Blends of two or more polyolefin copolymers may be used, if desired, as long as the density of the blend meets the requirements listed above for the single polyolefin copolymer.

The polyolefin may have Shore A hardness of about 96 or less (ASTM D2240, ISO 868). Preferably, the polyolefin has Shore A hardness of about 80 or less; more preferably, about 70 or less; most preferably, about 70 to about 50. The polyolefin may be blended with other polymeric materials as long as the Shore A hardness of the blend conforms to the above requirements.

The polyolefin compositions may include additives known in the art. The additives include plasticizers, processing aids, flow enhancing additives, flow reducing additives, lubricants, flame retardants, impact modifiers, nucleating agents to increase crystallinity, antiblocking agents such as silica, thermal stabilizers, UV absorbers, UV stabilizers, dispersants, surfactants, chelating agents, coupling agents, adhesives, primers and the like. One of ordinary skill in the art will recognize that additives may be added to the polyolefin composition using techniques known in the art or variants thereof, and will know the proper amounts for addition based upon typical usage. The total amount of additives used in the composition may be about 0.01 wt % to about 15 weight % based upon the weight of the polyolefin composition.

Thermal stabilizers are widely disclosed. Any known thermal stabilizer may be suitable. Preferred classes include but are not limited to phenolic antioxidants, alkylated monophenols, alkylthiomethylphenols, hydroquinones, alkylated hydroquinones, tocopherols, hydroxylated thiodiphenyl ethers, alkylidenebisphenols, O-, N- and S-benzyl compounds, hydroxybenzylated malonates, aromatic hydroxybenzyl compounds, triazine compounds, aminic antioxidants, aryl amines, diaryl amines, polyaryl amines, acylaminophenols, oxamides, metal deactivators, phosphites, phosphonites, benzylphosphonates, ascorbic acid (vitamin C), compounds that destroy peroxide, hydroxylamines, nitrones, thiosynergists, benzofuranones, indolinones, and the like and mixtures thereof. The polyolefin composition may contain any effective amount of thermal stabilizers. Use of thermal stabilizers is optional and in some instances is not preferred. When they are used, the polyolefin composition contains about 0.05 wt % to about 10 wt %, more preferably to about 5 wt %, and most preferably to about 1 wt %, of thermal stabilizers, based on the total weight of the polyolefin composition.

UV absorbers are widely disclosed. Any known UV absorber may be suitable. Preferred classes include but are not limited to benzotriazoles, hydroxybenzophenones, hydroxyphenyl triazines, esters of substituted and unsubstituted benzoic acids, and the like and mixtures thereof. The polyolefin composition may contain any effective amount of UV absorbers. Use of UV absorbers is optional and in some instances is not preferred. When they are used, the polyolefin composition contains about 0.05 wt % to about 10 wt %, more preferably to about 5 wt %, and most preferably to about 1 wt %, of UV absorbers, based on the total weight of the polyolefin composition.

Hindered amine light stabilizers (HALS) are widely disclosed. They include secondary, tertiary, acetylated, N-hydrocarbyloxy substituted, hydroxy substituted N-hydrocarbyloxy substituted, or other substituted cyclic amines that are characterized by a substantial amount of steric hindrance, due to aliphatic substitution on the carbon atoms adjacent to the amine function. The polyolefin composition may contain any effective amount of HALS. Use of HALS is optional and in some instances is not preferred. When they are used, the polyolefin composition contains about 0.05 wt % to about 10 wt %, more preferably to about 5 wt %, and most preferably, to about 1 wt %, of HALS, based on the total weight of the polyolefin composition.

The polyolefin compositions may contain additives that effectively reduce the melt flow of the resin, and may be present in any amount that permits production of thermoset compositions. Use of such additives may enhance the upper end-use temperature and reduce creep in the articles produced therefrom.

Melt flow reducing additives include organic peroxides such as 2,5-dimethylhexane-2,5-dihydroperoxide, 2,5-dimethyl-2,5-di(tert-butylperoxy)hexane-3, di-tert-butyl peroxide, tert-butylcumyl peroxide, 2,5-dimethyl-2,5-di(tert-butylperoxy)hexane, dicumyl peroxide, α,α′-bis(tert-butyl-peroxyisopropyl)benzene, n-butyl-4,4-bis(tert-butylperoxy)valerate, 2,2-bis(tert-butylperoxy)butane, 1,1-bis(tert-butyl-peroxy)cyclohexane, 1,1-bis(tert-butylperoxy)-3,3,5-trimethyl-cyclohexane, tert-butyl peroxybenzoate, benzoyl peroxide, and the like and mixtures combinations thereof. Preferably the organic peroxides decompose at a temperature of about 100° C. or higher to generate radicals. More preferably, the organic peroxides have a decomposition temperature that affords a half life of 10 hours at about 70° C. or higher to provide improved stability for blending operations. The organic peroxides may be added at a level of about 0.01 to about 10 wt %, or about 0.5 to about 3 wt %, based on the total weight of the polyolefin composition.

If desired, initiators, such as dibutyltin dilaurate, may also be present in the polyolefin composition at a level of about 0.01 to about 0.05 wt %, based on the total weight of the polyolefin composition. Also if desired, inhibitors such as hydroquinone, hydroquinone monomethyl ether, p-benzoquinone, and methylhydroquinone, may be added for the purpose of enhancing control of the reaction and stability. The inhibitors may be added at a level of less than about 5 wt %, based on the total weight of the composition.

Adhesion promoters and coupling agents may be incorporated into the polyolefin composition to promote even greater levels of adhesion to the substrate to which it is applied. Silane coupling agents are preferred for improving adhesive strength. Useful silane coupling agents include but are not limited to γ-chloropropylmethoxysilane, vinyltrimethoxysilane, vinyltriethoxysilane, vinyltris(β-methoxyethoxy)silane,γ-vinylbenzylpropyltrimethoxysilane, N-β-(N-vinylbenzylaminoethyl)-γ-aminopropyltrimethoxysilane, γ-methacryloxypropyltrimethoxysilane, vinyltriacetoxysilane, γ-glycidoxypropyltrimethoxysilane, γ-glycidoxypropyltriethoxysilane, β-(3,4-epoxycyclohexyl)ethyltrimethoxysilane, vinyltrichlorosilane, γ-mercaptopropylmethoxysilane, γ-aminopropyltriethoxysilane, N-β-(aminoethyl)-γ-aminopropyltrimethoxysilane, and mixtures of two or more thereof. The silane coupling agents may be preferably included in the polyolefin composition in about 0.01 to about 5 wt %, or more preferably about 0.05 to about 1 wt %, based on the total weight of the composition.

Abrasion-Resistant Substrate

The polyolefin layer preferably has a thickness of about 1 to about 12 mils (0.026-0.305 mm) and more preferably, a thickness of about 3 to about 7 mils (0.076-0.18 mm).

The abrasion-resistant polyolefin layer is an outermost layer arranged in overlaying or overlapping fashion to the substrate in order to provide its protective abrasion-resistant function. The polyolefin layer may be directly adjacent to the substrate or have other layers interposed between it and the substrate, provided that the polyolefin is the outermost layer. The polyolefin layer may be adhered to the substrate through the use of an adhesion primer, coating, or layer or it may be self-adhered. As used herein, when the polyolefin layer is said to be “self-adhered” to the substrate, it is meant that there is no intermediate layer such as a primer or thin adhesive layer between the substrate and the polyolefin layer. The polyolefin compositions have the advantage of forming high adhesion to the substrate.

The polyolefin layer may be produced by any suitable process. For example, the polyolefin layer may be formed on the substrate through dipcoating, solution casting, compression molding, injection molding, overmolding, lamination, melt extrusion, extrusion coating, tandem extrusion coating, or by any other procedures known to those of skill in the art. Preferably, films and sheets comprising the polyolefin composition are formed by melt extrusion, melt coextrusion, melt extrusion coating, or tandem melt extrusion coating processes and then laminated onto the substrate.

In many cases, the outermost abrasion-resistant polyolefin layer is intended to remain adhered to the substrate for the substrate's entire useful lifetime. In such cases it is desirable that the polyolefin layer is strongly or irreversibly adhered, either directly or through an intervening adhesive, to the substrate so that the film maintains structural integrity and adhesion to the substrate throughout its use. As used herein, the term “irreversibly adhered” means that adjacent layers cannot be separated by hand and the strength of the seal or bond between the layers is such that the layers cannot be separated without damage to one or both of the layers. Preferably, the peel strength (the amount of force required to remove to a film from a substrate) between the polyolefin layer and the substrate is greater than about 1000 g/inch, more preferably greater than about 2000 g/inch.

In other cases, it may be desirable for the abrasion-resistant polyolefin layer to be removed and/or replaced after it has been degraded to an extent that its reduced light transmission significantly inhibits the function of the substrate it is protecting. In such cases, the polyolefin layer acts “sacrificial layer.” When used as a sacrificial layer, removal of the polyolefin layer may be facilitated by several means.

For example, the polyolefin layer may be peelably adhered to the substrate, either directly or through an intervening adhesive layer. As used herein, the term “peelably adhered” means that there is an interfacial peelable seal between the polyolefin layer or intervening adhesive layer and the substrate, such that the film can be peeled cleanly from the substrate by hand. That is, the peel strength should be sufficient to withstand handling, processing, transportation, installation and use, but is low enough such that the films may be removed from the substrate by hand with relative ease at the appropriate time. For example, the peel strength is less than 1000 g/inch, preferably, from about 80 to about 400 g/inch, more preferably from about 100 to about 250 g/inch.

Thermally activated or heat activated adhesive compositions soften when heat is applied, adhere to a substrate and then harden, retaining adhesion.

Thermally activated adhesives are not tacky unless heated. The laminate may be heat sealed (thermally bonded) using any known method, included heated presses and calenders and the like, or by applying heat to the layers and then subsequently pressing them together without additional heat. The polyolefin may be attached to the substrate by high frequency (HF) welding. HF welding is an alternative to heat-bonding methods for adhering a film to a substrate by treatment with high frequency radiation to selectively heat a HF-active component or HF-active layer of a structure such as a multilayer film sufficiently to soften that component. In each case, the softened layer or component subsequently bonds the film structure to the substrate. In most cases peel strength is determined by sealing temperature, pressure and dwell time, so sealing conditions may be adjusted to provide the desired peal strength. A pressure-sensitive adhesive (PSA) remains tacky at ambient temperatures and requires pressure but not heat to effect adhesion. A PSA may be formulated to provide the desired level of adhesion between the polyolefin layer and the substrate.

When peeling a film from a substrate under stress at various angles of peel and speeds, it is important that the adhesion between the film and the substrate be interfacial. Interfacial adhesions are designed to fail at the interface of the adhesive surface and the substrate (i.e., the adhered layer peels cleanly away from the substrate layer), so that the polyolefin layer may be removed from the substrate completely.

Alternatively, only a portion of the polyolefin layer may be adhered to the substrate. For example, about 10 to about 40% of the contact area between the polyolefin layer and the substrate may be adhered and the remainder of the polyolefin layer is in contact with the substrate but is not adhered to it. The partial adherence may be at or near the perimeter of the polyolefin layer, in a pattern of discontinuous adhesion, or a combination thereof. A pattern of discontinuous adhesion may comprise a plurality of adhered dots or stripes distributed throughout the contact area between the polyolefin layer and the substrate. The partial adherence may be achieved by application of heat and/or pressure to selected areas of the polyolefin layer so that only those portions are adhered. HF welding may be particularly useful for effecting partial adherence, since the application of heat to selected areas by that method may be more precisely controlled than thermal bonding. An added HF-active layer may be necessary to use this method. An adhesive composition may be selectively applied to the polyolefin or substrate in the desired pattern.

Alternatively, the polyolefin composition may be in the form of a film or sheet that is mechanically held or fastened in overlaying fashion adjacent to the substrate but not adhered to it. Mechanical fastening includes the use of fasteners such as frames, clips, clamps and the like. The mechanical fastening is preferably limited to near the respective edges of the substrate and the grafted polyolefin layer, but it may also be provided in discontinuous fashion in the area where the layers overlay one another.

The substrate may take any form known in the art. For example, the substrate may be a molded or shaped article, such as a headlamp housing, light fixture, sign, film, sheet, safety laminate, windshield, window, solar cell module and the like. Preferably, at least a portion of the substrate is transparent. The substrate may be substantially planar, comprising two opposed faces with large surface areas and a relatively small thickness in relation to the faces. The abrasion-resistant layer is preferably adjacent to at least one of the opposed faces.

The substrate layers may be metal (such as aluminum foil) or polymeric. Preferably the film or sheet substrate is transparent. Polymeric film materials include, but are not limited to, polyesters (e.g., PET), poly(ethylene naphthalate), polycarbonate, polyolefins (e.g., polypropylene, polyethylene, and cyclic polyolefins), norbornene polymers, polystyrene (e.g., syndiotactic polystyrene), styrene-acrylate copolymers, acrylonitrile-styrene copolymers, polysulfones (e.g., polyethersulfone, and polysulfone), polyamides, polyurethanes, acrylic polymers, cellulose acetates (e.g., cellulose acetate and cellulose triacetates), cellophane, vinyl chloride polymers (e.g., polyvinylidene chloride and vinylidene chloride copolymers), fluoropolymers (e.g., polyvinyl fluoride, polyvinylidene fluoride, polytetrafluoroethylene, and ethylene-tetrafluoroethylene copolymers), and combinations of two or more thereof. Preferably the abrasion-resistant polyolefin layer is an outermost layer on a polymeric film substrate comprising a polymeric material selected from the group consisting of biaxially oriented polyester film (preferably poly(ethylene terephthalate) film) or a fluoropolymer film (e.g., TEDLAR, TEFZEL, and TEFLON films from E. I. du Pont de Nemours and Company (DuPont)). Fluoropolymer-polyester-fluoropolymer (“TPT”) films are also preferred for some applications. The polyolefin layer may be applied to a preformed film substrate by, for example, extrusion coating or lamination processes, or may be formed directly by, for example, coextrusion or multilayer blown film processes. By “laminated”, it is meant that, within a laminated structure, the two layers are bonded either directly (i.e., without any additional material between the two layers) or indirectly (i.e., with additional material, such as adhesive materials, between the two layers). Preferably, the polyolefin layer is directly laminated or bonded to the film or sheet substrate.

If desired, one or both surfaces of the film and sheet substrates may be treated to enhance adhesion to the polyolefin layer. Adhesion enhancing treatment may take any form known in the art and includes flame treatments (e.g., U.S. Pat. Nos. 2,632,921; 2,648,097; 2,683,894; and 2,704,382), plasma treatments (e.g., U.S. Pat. No. 4,732,814), electron beam treatments, oxidation treatments, corona discharge treatments, chemical treatments, chromic acid treatments, hot air treatments, ozone treatments, ultraviolet light treatments, sand blast treatments, solvent treatments, and combinations of two or more thereof. The adhesion strength may be further improved by applying an adhesive or primer coating on the surface of the layer(s). For example, U.S. Pat. No. 4,865,711 discloses a film or sheet that has a thin layer of carbon deposited on one or both surfaces for improved bondability. Other adhesives or primers include silanes, poly(allyl amine) based primers (e.g., U.S. Pat. Nos. 5,411,845; 5,770,312; 5,690,994 and 5,698,329) and acrylic based primers (e.g., U.S. Pat. No. 5,415,942). The adhesive or primer coating may be a monolayer of the adhesive or primer and have a thickness of about 0.0004 to about 1 mil (about 0.00001 to about 0.03 mm), preferably, about 0.004 to about 0.5 mil (about 0.0001 to about 0.013 mm), more preferably, about 0.004 to about 0.1 mil (about 0.0001 to about 0.003 mm).

More preferably, the substrate sheet is transparent and rigid. The rigid sheets may comprise a material with a modulus of about 100,000 psi (690 MPa) or greater (as measured by ASTM Method D-638) and may be formed, for example, of glass, metal, ceramic, or polymers including polycarbonate, acrylic, polyacrylate, cyclic polyolefin, metallocene-catalyzed polystyrene and combinations of two or more thereof. The term “glass” includes any type of glass. Suitable types of glass include, but are not limited to, window glass, plate glass, silicate glass, sheet glass, low iron glass, tempered glass, tempered CeO-free glass, float glass, borosilicate glass, low density glass, annealed glass, heat strengthened glass, silica glass, chemically strengthened glass, colored glass, specialty glass (e.g., glass with functional additives(s), such as those controlling solar heating), coated glass (e.g., glass that is coated with sputtered metals, such as silver or indium tin oxide), E-GLASS, TOROGLASS, and SOLEX glass (Solutia, Inc., St. Louis, Mo.). For example, U.S. Pat. Nos. 4,615,989; 5,173,212; 5,264,286; 6,150,028; 6,340,646; 6,461,736; and 6,468,934 describe specialty glass and US20070060465 and WO2003068501 describes chemically strengthened glass. The type of glass used is determined based on the intended use. The grafted polyolefin layer may be applied to the sheet substrate as described above.

Abrasion-Resistant Safety Laminate

The invention includes a long lifetime, highly abrasion-resistant safety laminate for use in a wide range of aggressive environmental conditions comprising an outermost layer with a thickness of about 0.1 to about 20 mils (0.0026 to 0.51 mm) comprising the polyolefin composition.

The abrasion-resistant safety laminate is a laminated article that comprises at least one rigid sheet or film layer as described above and at least one polymeric interlayer sheet, wherein one or both of the outermost layers comprise the polyolefin layer. The polymeric interlayer sheet may be formed of any polymeric material, such as, poly(vinyl acetal) (e.g., poly(vinyl butyral) (PVB)), poly(vinyl chloride) copolymer, polyurethane, poly(ethylene vinyl acetate), acid copolymer, ionomer, polyolefin, metallocene polyolefin, acid- or anhydride-functional polyolefin, silane-functional polyolefin, polyolefin block elastomers, copolymers of α-olefins and α,β-ethylenically unsaturated carboxylic acid esters (e.g., ethylene methyl acrylate copolymers and ethylene butyl acrylate copolymers), silicone elastomers, epoxy resins, and combinations of two or more thereof. When two or more interlayer sheets are incorporated in the safety laminate, they may be formed of common or different polymeric materials.

Preferably, the abrasion-resistant safety laminate is a laminated article comprising a rigid sheet/interlayer/rigid sheet or a rigid sheet/interlayer/film structure, wherein one or both of the outermost layers comprise the polyolefin layer. More preferably, the abrasion-resistant safety laminate is a laminated article comprising a glass sheet/interlayer/glass sheet or a glass sheet/interlayer/poly(ethylene terephthalate) film structure, wherein one or both of the outermost layers comprise the polyolefin layer.

The polyolefin layer may be applied to the safety laminate component layers prior to the lamination process; applied during the lamination process as the outermost safety laminate layer(s); or applied to a preformed safety laminate. Preferably, the polyolefin layer is a preformed polyolefin film and is applied to a preformed safety laminate.

Safety laminates may have a 7-to-10-year lifetime in automobiles, but may extend to as long as 30 years or longer in architectural uses, such as windows in buildings. Under aggressive conditions (e.g., wind blown sand) the transparency of safety laminates may drastically decline in only a few years due to pitting, significantly degrading the use for which safety laminates are designed. The abrasion-resistant polyolefin layer provides significant protection from such environmental hazards to the safety laminates when used as an outermost layer. The polyolefin layer may also serve as a sacrificial layer and be replaced on a frequency required to maintain optimum transparency since it is inexpensive relative to the safety laminate.

Abrasion-Resistant Solar Cell Modules

The invention includes a long lifetime, highly abrasion-resistant solar cell module for use in a wide range of aggressive environmental conditions comprising an outermost layer with a thickness of about 0.1 to about 20 mils (0.0026 to 0.51 mm) comprising the polyolefin composition.

The term “solar cell” is meant to include any article that can convert light into electrical energy. Solar cells include but are not limited to wafer-based solar cells (e.g., c-Si or mc-Si based solar cells) and thin film solar cells (e.g., a-Si, μc-Si, CdTe, or CI(G)S based solar cells).

Monocrystalline silicon (c-Si), poly- or multi-crystalline silicon (poly-Si or mc-Si) and ribbon silicon are the materials used most commonly in forming wafer-based solar cells. Wafer-based solar cell modules often comprise a series of self-supporting wafers (or cells) that are soldered together. The wafers may have a thickness of about 180 to about 240 μm. Such a panel of solar cells is called a solar cell layer. Within the solar cell layer, it is preferred that the solar cells are electrically interconnected and/or arranged in a flat plane. The solar cell layer may further comprise electrical wirings such as cross ribbons connecting the individual cell units and bus bars having one end connected to the cells and the other exiting the module. The solar cell layer is further laminated to encapsulant layer(s) and protective layer(s) to form a weather resistant module that may be used for up to 25 to 30 years. A wafer-based solar cell may comprise, in order of position from the front light-receiving side to the back non-light-receiving side: (1) an incident layer, (2) a front encapsulant layer, (3) a solar cell layer, (4) a back encapsulant layer, and (5) a backing layer.

The increasingly important thin film solar cells may be formed from materials that include amorphous silicon (a-Si), microcrystalline silicon (μc-Si), cadmium telluride (CdTe), copper indium selenide (CuInSe2 or CIS), copper indium/gallium diselenide (CuInxGa(1-x)Se2 or CIGS), light absorbing dyes, and organic semiconductors. Thin film solar cells are disclosed in e.g., U.S. Pat. Nos. 5,507,881; 5,512,107; 5,948,176; 5,994,163; 6,040,521; 6,137,048; and 6,258,620; US20070298590; US20070281090; US20070240759; US20070232057; US20070238285; US20070227578; US20070209699; and US20070079866. Thin film solar cells with a thickness of less than 2 μm may be produced by depositing the semiconductor layers onto a superstrate or substrate formed of glass or a flexible film. During manufacture, it is common to include a laser scribing sequence that enables the adjacent cells to be directly interconnected in series, with no need for further solder connections between cells. As with wafer cells, the solar cell layer may further comprise electrical wirings such as cross ribbons and bus bars. Similarly, thin film solar cells are further laminated to other encapsulant and protective layers to produce a weather resistant and environmentally robust module. Depending on the sequence in which the multi-layer deposition is carried out, the thin film solar cells may be deposited on a superstrate that ultimately serves as the incident layer in the final module, or the cells may be deposited on a substrate that ends up serving as the backing layer in the final module. Therefore, a thin film solar cell module may have one of two types of construction. The first type includes, in order of position from the front light-receiving side to the back non-light-receiving side, (1) a solar cell layer comprising a superstrate and a layer of thin film solar cell(s) deposited thereon at the non-light-receiving side, (2) a (back) encapsulant layer, and (3) a backing layer. The second type may include, in order of position from the front light-receiving side to the back non-light-receiving side, (1) an incident layer, (2) a (front) encapsulant layer, (3) a solar cell layer comprising a layer of thin film solar cell(s) deposited on a substrate backing layer at the light-receiving side thereof.

The solar cell module typically comprises at least one layer of an encapsulant sheet (described above as a polymeric interlayer sheet) which is laminated to the solar cell layer. By “laminated”, it is meant that, within a laminated structure, the two layers are bonded either directly (i.e., without any additional material between the two layers) or indirectly (i.e., with additional material, such as interlayer or adhesive materials, between the two layers). The solar cell module may further comprise additional encapsulant layers.

The solar cell module may further comprise an incident layer and/or a backing layer of the module at the light-receiving side and the non-light-receiving side of the solar cell module, respectively. The incident layer and the backing layer may be derived from any suitable sheets or films, such as described above.

The solar cell module may further comprise other functional film or sheet layers (e.g., dielectric layers or barrier layers) embedded in the module. Such functional layers may be derived from any of the above mentioned polymeric films or those that are coated with additional functional coatings. For example, poly(ethylene terephthalate) films coated with a metal oxide coating, such as those disclosed in U.S. Pat. Nos. 6,521,825 and 6,818,819 and EP1182710, may function as oxygen and moisture barrier layers in the laminates.

If desired, a layer of nonwoven glass fiber (scrim) may also be included between the solar cell layers and the encapsulants to facilitate deaeration during the lamination process or to serve as reinforcement for the encapsulants. Use of scrim layers is known (U.S. Pat. Nos. 5,583,057; 6,075,202; 6,204,443; 6,320,115; and 6,323,416; and EP0769818).

The film or sheet layers positioned to the light-receiving side of the solar cell layer are preferably made of transparent material to allow efficient transmission of sunlight into the solar cells. The light-receiving side of the solar cell layer may sometimes be referred to as a front side and in actual use conditions would generally face a light source. The non-light-receiving side of the solar cell layer may sometimes be referred to as a lower or back side and in actual use conditions would generally face away from a light source. A special film or sheet may be included to serve both the function of an encapsulant layer and an outer layer. It is also conceivable that any of the film or sheet layers included in the module may be in the form of a pre-formed single-layer or multi-layer film or sheet.

A series of the solar cell modules described above may be linked to form a solar cell array to produce desired voltage and current.

Wafer-based solar cell modules may comprise, in order of position from the front light-receiving side to the back non-light-receiving side, (a) an incident layer, (b) a front encapsulant layer, (c) a solar cell layer comprising one or more electrically interconnected solar cells, (d) a back encapsulant layer, and (e) a backing layer, wherein at least one or both of the incident layer and the backing layer comprise an outermost polyolefin layer. Preferably, the incident layer comprises an outermost polyolefin layer.

Thin film solar cell modules may comprise in order of position from the front light-receiving side to the back non-light-receiving side

(i) (a) a solar cell layer comprising a substrate and a layer of thin film solar cell(s) deposited thereon at the non-light-receiving side, (b) a (back) encapsulant layer, and (c) a backing layer or

(ii) (a) a transparent incident layer, (b) a (front) encapsulant layer, and (c) a solar cell layer comprising a layer of thin film solar cell(s) deposited on a substrate at the light-receiving side thereof; wherein at least one or both of the incident layer and the backing layer comprises an outermost polyolefin layer. Preferably, the incident layer comprises an outermost polyolefin layer.

The polyolefin layer may be applied to the solar cell module component layers prior to the lamination process; applied during the lamination process as the outermost solar cell module layer(s); or applied to a preformed solar cell module. Preferably, the polyolefin layer is a preformed polyolefin film that is applied to a preformed solar cell module.

Solar cell modules may have a guaranteed power output for 20 to 30 years. In aggressive environments (e.g., with wind-blown sand) solar cell module power output may drastically decline in only a few years because of pitting of the incident layer. The abrasion-resistant polyolefin layer provides significant protection from such environmental hazards to the solar cell modules when used as an outermost layer. The grafted polyolefin layer may also serve as a sacrificial layer and be replaced on a frequency required to maintain optimum power output since it is inexpensive relative to the solar cell module.

### Examples

Shore A hardness is measured according to ASTM D2240, ISO 868.

### Materials Used

PO1: PURELL® 5037L, a product of the Basell Polyolefins, LyondellBasell Corporation, Rotterdam, The Netherlands, described as a high density polyethylene (density 0.952 g/cc) and had a Shore A hardness of 100.
PO2: ENGAGE®7270, a product of The Dow Chemical Company, Midland, Mich., described as a poly(ethylene-co-butene) (density 0.880 g/cc) with Shore A hardness of 80.
PO3: ENGAGE® 8180, a product of The Dow Chemical Company, Midland, Mich., described as a poly(ethylene-co-octene) (density 0.863 g/cc) with Shore A hardness of 63.
PO4: ENGAGE® 7380, a product of The Dow Chemical Company, Midland, Mich., described as a poly(ethylene-co-butene) (density 0.870 g/cc) with Shore A hardness of 66.

### Comparative Example CE 1 and Examples 1-3

Abrasion resistance was assessed according to the following procedure. Wear test coupons, 50 mm by 50 mm by 3.175 mm thick, were cut from injection molded plaques of the polyolefins summarized in Table 1. The wear test coupon for Comparative Example CE 1 had a thickness of 6.35 mm. The wear test coupons were dried in a vacuum oven (20 inches Hg) at a temperature of 35° C. until the weight loss was less than 1 mg/day and weighed. The wear test coupons were mounted in a test chamber and a 10 wt % aqueous sand (AFS50-70 test sand) slurry at a temperature of 50° C. was impinged on the wear test coupon through a slurry jet nozzle positioned 100 mm from its surface with a diameter of 4 mm at a slurry jet rate of 15-16 meters/second with a slurry jet angle of 90° relative to the surface plane for 2 hours. The wear test coupons were then removed and dried in a vacuum oven (20 inches Hg) at room temperature for at least 15 hours and then reweighed. The results are reported in Table 1.

TABLE 1

| | | | 2 | 3 |
|---|---|---|---|---|
| | | 1 | Final | Weight |
| Example | Material | Initial wt (g) | wt (g) | loss (mg) |
| CE1 | PO1 | 13.4787 | 13.4461 | 32.6 |
| 1 | PO2 | 13.069 | 13.0673 | 1.7 |
| 2 | PO3 | 11.334 | 11.3338 | 0.2 |
| 3 | PO4 | 11.0653 | 11.0653 | 0 |

1. An article comprising a substrate and an outermost layer wherein
the innermost layer has a thickness of about 0.0026 to about 0.51 mm and comprises a polyolefin composition; and
the polyolefin comprises ethylene and an α-olefin having 3 to 20 carbons having a density of about 0.92 g/cc (ASTM D-792) or less.

2. The article of claim 1 wherein the polyolefin has a density of about 0.90 g/cc or less; the polyolefin comprises from about 5 wt % to about 50 wt % of the α-olefin comonomer based on the total weight of the parent polyolefin copolymer.

3. The article of claim 2 wherein the polyolefin has a Shore A hardness of about 80 or less and the polyolefin outermost layer has a thickness of about 0.076 to about 0.18 mm.

4. The article of claim 3 wherein at least a portion of the substrate is transparent.

5. The article of claim 4 wherein the substrate is biaxially oriented polyester film, fluoropolymer film, fluoropolymer-polyester-fluoropolymer film, glass, metal, ceramic, or polymer and the polymer is polycarbonate, acrylic, polyacrylate, cyclic polyolefin, metallocene-catalyzed polystyrene, or combinations of two or more thereof.

6. The article of claim 1 wherein the article is at least one molded or shaped article, sign, film, sheet, safety laminate, solar cell module, building glazing, vehicle window, windshield, headlamp, or lighting fixture.

7. The article of claim 5 wherein the article is at least one molded or shaped article, sign, film, sheet, safety laminate, solar cell module, building glazing, vehicle window, windshield, headlamp, or lighting fixture.

8. The article of claim 7 wherein
the article is the safety laminate;
the substrate comprises at least one rigid sheet or film layer and at least one polymeric interlayer;
the film is biaxially oriented polyester, fluoropolymer, fluoropolymer-polyester-fluoropolymer, or combinations of two or more thereof
the interlayer adheres to or is in contact with the outermost layer.

9. The article of claim 8 wherein the substrate comprises the rigid sheet and the rigid sheet is glass.

10. The article of claim 7 wherein
the article is the safety laminate;
the substrate comprises, in the order, a rigid sheet, an interlayer, and a second rigid sheet or a film layer; and
the film is biaxially oriented polyester film, fluoropolymer film, fluoropolymer-polyester-fluoropolymer film, or combinations of two or more thereof.

11. The article of claim 10 wherein the rigid sheet is glass.

12. The article of claim 7 wherein the article is the solar cell module; the substrate comprises, in the order from the front light-receiving side to the back non-light-receiving side of the solar cell module, (a) an incident layer, (b) a front encapsulant layer, (c) a solar cell layer comprising one or more electrically interconnected solar cells, (d) a back encapsulant layer, and (e) a backing layer; and the outermost layer is the incident layer or the backing layer.

13. The article of claim 12 wherein the outermost layer is the incident layer and the backing layer.

14. The article of claim 12 wherein the solar cell layer comprises a second substrate having deposited thereon a layer of thin film solar cell(s); and the layer of thin film solar cell(s) is adhered to the back encapsulant layer.

15. The article of claim 12 wherein the incident layer is transparent; the solar cell layer comprises a second substrate having deposited thereon a layer of thin film solar cell(s); and the layer of thin film solar cell(s) is adhered to the front encapsulant layer.
